(19) United States
(12) Patent Application Publication
(10) Pub. No.: US 2025/0052793 A1
(43) Pub. Date: Feb. 13, 2025

(54) HHT-BASED VOLTAGE QUALITY DISTURBANCE DETECTION METHOD

(71) Applicants: STATE GRID ZHEJIANG JIASHAN POWER SUPPLY CO., LTD., Zhejiang (CN); STATE GRID ZHEJIANG JIAXING POWER SUPPLY CO., LTD., Zhejiang (CN)

(72) Inventors: Quanfei HUANG, Zhejiang (CN); Sheng JIN, Zhejiang (CN); Chongbiao ZHANG, Zhejiang (CN); Keke LIU, Zhejiang (CN); Bin CAO, Zhejiang (CN); Jinwei CHEN, Zhejiang (CN); Lei GUO, Zhejiang (CN); Shupei HAN, Zhejiang (CN); Weijian JIANG, Zhejiang (CN); Xueyu MA, Zhejiang (CN)

(73) Assignees: STATE GRID ZHEJIANG JIASHAN POWER SUPPLY CO., LTD., Zhejiang (CN); STATE GRID ZHEJIANG JIAXING POWER SUPPLY CO., LTD., Zhejiang (CN)

(21) Appl. No.: 18/929,673

(22) Filed: Oct. 29, 2024

Related U.S. Application Data
(63) Continuation-in-part of application No. PCT/CN2023/103020, filed on Jun. 28, 2023.

(30) Foreign Application Priority Data
Nov. 25, 2022 (CN) 202211494196.5

(51) Int. Cl. G01R 23/16; G01R 19/00

(52) U.S. Cl. CPC G01R 23/16; G01R 19/0084

(57) ABSTRACT

A HHT-based voltage quality disturbance detection method, including: obtaining frequency spectrum information of an original voltage signal, and determining whether the original voltage signal is a closely spaced mode signal; based on the frequency spectrum information, performing a singular value decomposition on the original voltage signal and performing a reconstruction to obtain a reconstructed voltage signal with an interference signal removed; if the original voltage signal is the closely spaced mode signal, performing a frequency modulation on the reconstructed voltage signal to obtain a frequency-modulated signal; adding white noise to the reconstructed voltage signal or the frequency-modulated signal, and then performing an empirical mode decomposition; and performing a Hilbert transform on each intrinsic mode function obtained by the empirical mode decomposition to obtain an amplitude and frequency information of a corresponding intrinsic mode function.

### CROSS-REFERENCE TO RELATED APPLICATION

This is a continuation-in-part application of International Application No. PCT/CN2023/103020, filed on Jun. 28, 2023, which claims the priority benefits of China Application No. 202211494196.5, filed on Nov. 25, 2022. The entirety of each of the above-mentioned patent applications is hereby incorporated by reference herein and made a part of this specification.

### TECHNICAL FIELD

The present invention relates to the technical field of power quality, and in particular to an HHT-based voltage quality disturbance detection method.

### DESCRIPTION OF RELATED ART

Hilbert-Huang transform (Hilbert-Huang Transform, HHT) is the most commonly used disturbance detection technology, which has a faster computation speed than S-transform and is more appropriate for composite disturbance detection, and which is more appropriate for processing a non-stationary signal detection compared with analysis methods such as Fourier and wavelet transform that require a priori function basis. The HHT method includes empirical mode decomposition (Empirical Mode Decomposition, EMD) and Hilbert transform. Specifically, an initial signal is transformed into a set of mode functions of different scales by the EMD, and then instantaneous amplitude and frequency characteristics corresponding to all the mode functions are obtained through the Hilbert transform, so that specific changes in the signal are obtained. An existing HHT encounters mode mixing in voltage quality disturbance detection, which is manifested as follows: after the original signal is decomposed through the EMD, different intrinsic mode functions (Intrinsic Mode Function, IF) are distributed at different time scales, so that the IMF cannot accurately obtain a time-frequency characteristic of the signal, and it is difficult to accurately detect voltage quality disturbance.

A Method for Positioning and Detecting Harmonic Sources in Power Grid published in a Chinese patent document, with the publication number CN113092931A and filed on Jul. 9, 2021, includes the following steps: step 1: using a window function method to design an FIR digital low-pass filter to filter out out-of-band high-frequency electromagnetic interference; and step 2: using an HHT algorithm to detect transmission harmonic interference in a power grid system. In the method of the present invention, the out-of-band high-frequency electromagnetic interference in the power grid is filtered out, and the harmonic detection and positioning are performed based on the HHT algorithm, featuring a low computational amount of a processing method, a simple system structure, a high frequency resolution, and low costs. In the method, the HHT method is used to detect a harmonic frequency and amplitude, as well as a disturbance time, a frequency, and an amplitude of a power quality disturbance signal (voltage sag, voltage bulge, voltage discontinuity, transient oscillation, transient pulse, and the like). However, this method does not resolve the mode mixing encountered in the process of the Hilbert Huang transform, so that the IMF cannot accurately obtain the time-frequency characteristic of the signal, and it is difficult to accurately detect the voltage quality disturbance.

### SUMMARY

In the present invention, to overcome a problem that mode mixing exists when Hilbert-Huang transform is used for disturbance detection, so that an intrinsic mode function cannot accurately obtain a time-frequency characteristic of a signal, and it is difficult to accurately detect voltage quality disturbance, an HHT-based voltage quality disturbance detection method is provided. An original voltage signal is transformed into a form of a Hankel matrix, singular value decomposition and reconstruction are performed to remove an interference signal, and frequency modulation and empirical mode decomposition are performed on the signal, so that mode mixing existing during HHT can be prevented, and the accuracy of voltage quality disturbance detection can be improved.

To achieve the foregoing purpose, the following technical solutions are used in the present invention.

The HHT-based voltage quality disturbance detection method includes:
obtaining frequency spectrum information of an original voltage signal, and determining whether the original voltage signal is a closely spaced mode signal;
based on the frequency spectrum information, performing singular value decomposition and reconstruction on the original voltage signal, to obtain a reconstructed voltage signal with an interference signal removed;
if the original voltage signal is the closely spaced mode signal, performing frequency modulation on the reconstructed voltage signal, to obtain a frequency-modulated signal;
adding white noise to the reconstructed voltage signal or frequency-modulated signal, and then performing empirical mode decomposition; and
performing Hilbert transform on each intrinsic mode function obtained by the empirical mode decomposition, to obtain amplitude and frequency information of the corresponding intrinsic mode function, to complete detection of voltage quality disturbance.

In the present invention, frequency spectrum analysis is performed on the original voltage signal, and a frequency and an amplitude of each order of mode contained in the obtained signal are determined. Based on a result of the frequency spectrum analysis, it is determined whether the signal is a closely spaced mode signal. When the signal is the closely spaced mode signal, frequencies of all orders of modes in the signal are too similar, so that the HHT cannot correctly separate the frequencies, causing mode mixing. Therefore, improvement based on singular value decomposition and reconstruction and signal frequency modulation needs to be performed on the original voltage signal, and then Hilbert-Huang Transform needs to be performed, to prevent mode mixing, improving the accuracy of voltage quality disturbance detection. Finally, the Hilbert transform is performed on the intrinsic mode function obtained by decomposition, to obtain the amplitude and frequency information for determining voltage disturbance. In addition, white noise is added to the signal to be decomposed during decomposition of the intrinsic mode function, to further eliminate the influence of the mode mixing.

Preferably, the determining whether the original voltage signal is a closely spaced mode signal includes:
for the original voltage signal α₁ cos(2πf₁t+φ₁)+α₂ cos(2πf₂t+φ₂), when f₁/f₂>α is not met and α₁f₁>α₂f₂, determining that the original voltage signal is the closely spaced mode signal, where α₁ and α₂ are amplitudes of the corresponding signal, f₁ and f₂ are frequencies of the corresponding signal, and f₁>f₂, φ₁ and φ₂ are initial phase angles of the corresponding signal, and α is a set frequency ratio that is greater than 1.

When the frequencies of the signal are similar in the present invention, the signal can be regarded as a special amplitude-modulated signal, and the signal meets that a mean value of extremum envelopes is zero and the number of zero-crossing points is the same as the number of extremum points or there is a difference of one, so the model mixing occurs when the HHT decomposition is directly used. Therefore, frequency spectrum analysis needs to be performed on the original voltage signal to determine whether the mode mixing occurs. A signal with a larger value between signal frequencies f₁ and f₂ is selected to divide a signal with a smaller value to obtain a frequency ratio α. As the frequency ratio is greater, a frequency difference between the two signals is greater, which means that the mode mixing does not occur easily, and a frequency ratio of 2 can be selected as a standard for determining whether the original voltage signal is the closely spaced mode signal.

Preferably, performing singular value decomposition and reconstruction, to obtain a reconstructed original voltage signal includes:
based on the original voltage signal x₀(i), (i=1,2, . . . , N), constructing a corresponding Hankel matrix H and performing the singular value decomposition, to obtain a singular value matrix

$$D = [ \begin{matrix}Σ & 0 \\ 0 & 0\end{matrix} ] ,$$

where the number of rows of the matrix H is m, the number of columns of the matrix H is n=N−m+1, a rank is r, Σ=diag (σ₁, σ₂, . . . , σᵣ) in the singular value matrix, and singular values meet σ₁>σ₂> . . . >σᵣ>0;
retaining singular values among the first effective singular values, setting singular values following the effective singular values to zero, and updating the singular value matrix; and
performing inverse operation of singular value decomposition on an updated singular value matrix, to obtain the reconstructed voltage signal x(i) with the interference signal removed.

The number of rows m of the matrix in the Hankel matrix in the present invention is half of the length of the original voltage signal N. The voltage signal can be regarded as including a disturbance signal and an interference signal. In addition, because singular values in the singular value matrix are arranged in decreasing order, which reflects specific energy concentration of the signal, and the signal is decomposed based on specific singular values. A smaller singular value is set to 0, and the interference signal in the original voltage signal can be removed.

Preferably, the number of effective singular values is the number of main frequencies of the original voltage signal multiplied by a set multiple; and for the singular values among the first effective singular values, when a singular value is greater than p times a next singular value, all singular values following the singular value are set to zero, and p is a preset positive number less than 1.

In the present invention, it is determined that some singular values in the singular value matrix are set to zero, so that after the number of singular values following the effective singular values are set to zero, the singular values among the first effective singular values are processed. If a numerical difference between two adjacent singular values is too large, it indicates that a next singular value and a singular value following the next singular value are interference signals, which also need to be set to zero. In the present invention, the number of effective singular values is determined based on the number of main frequencies in the frequency spectrum information, which may be twice of the main frequency. If there is a difference between two adjacent singular values, p=5 can be selected as a threshold.

Preferably, the steps of frequency modulation on the reconstructed voltage signal are as follows:
performing Hilbert transform on the reconstructed voltage signal x(t) to obtain an analytic signal X(t) thereof

$$X ( t ) = x ( t ) + jH [ x ( t ) ] = {e}^{j {ω}_{1} t} + {e}^{j {ω}_{2} t} ,$$

where ω₁=2πf₁ and ω₂=2πf₂; and
selecting a modulation frequency ω₀ to perform frequency modulation and transform on the analytic signal X(t), to obtain the frequency-modulated signal

$$Z ( t ) = X ( t ) \cdot {e}^{- j {ω}_{0} t} = {Z}_{r} ( t ) + {jZ}_{j} ( t ) = {e}^{j ( {ω}_{1} - {{ω}_{0}}_{} ) t} + {e}^{j ( {ω}_{2} - {{ω}_{0}}_{} ) t} ,$$

where Zᵣ(t) is a transformed real part of the frequency-modulated signal Z(t), and jZⱼ(t) is a transformed imaginary part of the frequency-modulated signal Z(t).

In the present invention, the original voltage signal is determined as the closely spaced mode signal, and then frequency modulation needs to be performed on the reconstructed voltage signal. Through signal frequency modulation, closely spaced mode separation can be implemented indirectly, preventing mode mixing caused by interaction of closely spaced modes. A core idea is to subtract frequencies of adjacent modes from proper frequencies of frequency modulation through signal frequency modulation, amplify a frequency ratio, so that a frequency-modulated signal becomes a non-closely spaced mode signal, and then perform empirical mode decomposition on the frequency-modulated signal.

Preferably, after the frequency modulation is completed, white noise is added to the real part and the imaginary part of the frequency-modulated signal Z(t) separately, and empirical mode decomposition and combination are performed, to obtain a decomposition expression of the frequency-modulated signal Z(t); and
the decomposition expression of the frequency-modulated signal Z(t) is multiplied by e^{jω}^{₀}^{t} to obtain a decomposition expression of the analytic signal X(t), and a real part of the decomposition expression of the analytic signal X(t) is taken as a decomposition expression of the reconstructed voltage signal x(t), so that empirical mode decomposition of the reconstructed voltage signal is completed.

The empirical mode decomposition is performed on the frequency-modulated signal, to obtain a sum of several intrinsic mode functions IMF and residuals. Then, through the frequency-modulation inverse transformation on the intrinsic mode function IMF, intrinsic mode functions IMFs of a real reconstructed voltage signal are obtained. Empirical mode decomposition is performed on the real part and imaginary part of the frequency-modulated signal constructed from the reconstructed voltage signal, preventing mode mixing caused by direct empirical mode decomposition on the voltage signal.

Preferably, selection of the modulation frequency ω₀ needs to meet

$$\frac{{ω}_{1} - {ω}_{0}}{{ω}_{2} - {ω}_{0}} > α ,$$

where ω₁−ω₀>0, ω₂−ω₀>0.

In the present invention, when the modulation frequency is selected, a frequency ratio after frequency modulation needs to be greater than a set α, so that the original voltage signal is changed from the closely spaced mode signal to the non-closely spaced mode signal. For two frequencies with a frequency ratio less than α, a proper modulation frequency ω₀ is subtracted from both a numerator and denominator, so that signal frequencies are reduced and a frequency ratio of the signal is amplified to be greater than α, thereby completing frequency modulation.

The present invention has the following beneficial effects: the original voltage signal is transformed into a form of a Hankel matrix, the singular value decomposition and reconstruction are performed to remove the interference signal, and frequency modulation and empirical mode decomposition are performed on the signal, so that mode mixing existing during HHT can be prevented, and the accuracy of voltage quality disturbance detection can be improved.

### BRIEF DESCRIPTION OF THE DRAWINGS

FIG. 1 is a flow chart of a voltage quality disturbance detection method according to the present invention.

FIG. 2 a time-domain diagram of a voltage signal according to an embodiment of the present invention.

FIG. 3 is a schematic diagram of empirical mode decomposition in the detection method of the present invention according to an embodiment of the present invention.

FIG. 4 is a schematic diagram of direct empirical mode decomposition according to an embodiment of the present invention.

### DESCRIPTION OF THE EMBODIMENTS

The present invention will be further described below with reference to the accompanying drawings and specific implementations.

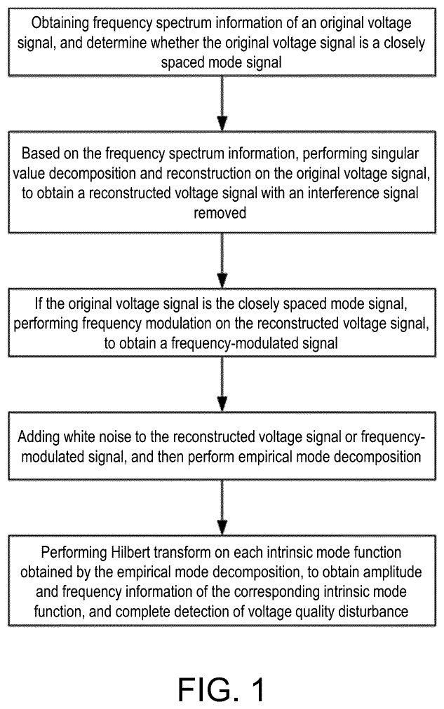

FIG. 1 shows an HHT-based voltage quality disturbance detection method, including:
obtaining an original voltage signal for frequency spectrum analysis, determining frequency spectrum information of the original voltage signal, and determining whether the original voltage signal is a closely spaced mode signal;
based on the frequency spectrum information, performing singular value decomposition and reconstruction on the original voltage signal, to obtain a reconstructed voltage signal with an interference signal removed;
if the original voltage signal is the closely spaced mode signal, performing frequency modulation on the reconstructed voltage signal to obtain a frequency-modulated signal, and then performing empirical mode decomposition; if the original voltage signal is a non-closely spaced mode signal, directly performing empirical mode decomposition on the reconstructed voltage signal, or performing frequency modulation and then performing empirical mode decomposition on the reconstructed voltage signal; and adding noise to the reconstructed voltage signal or frequency-modulated signal, and then performing empirical mode decomposition; and
performing Hilbert transform on each intrinsic mode function after empirical mode decomposition, to obtain amplitude and frequency information of the corresponding intrinsic mode function, and completing detection of voltage quality disturbance.

It should be noted that in the present invention, first, frequency spectrum analysis is performed on the original voltage signal, and a frequency and an amplitude of each order of mode contained in the obtained signal are determined. Based on a result of the frequency spectrum analysis, it is determined whether the signal is the closely spaced mode signal. When the signal is the closely spaced mode signal, frequencies of all orders of modes in the signal are too similar, so that the HHT cannot correctly separate the frequencies, causing mode mixing. Therefore, improvement based on singular value decomposition and reconstruction and signal frequency modulation needs to be performed on the original voltage signal, and then Hilbert-Huang transform needs to be performed, to prevent mode mixing, improving the accuracy of voltage quality disturbance detection. Finally, the Hilbert transform is performed on the intrinsic mode function obtained by decomposition, to obtain the amplitude and frequency information for determining voltage disturbance. In addition, white noise is added to the signal to be decomposed during decomposition of the intrinsic mode function, to further eliminate the influence of the mode mixing.

It is worth noting that the mode mixing is manifested as follows: components are distributed in different intrinsic mode functions at a same time scale, so that the intrinsic mode functions cannot accurately reflect a time-frequency characteristic of the signal. Generally, when there is a high-frequency discontinuous signal in the signal, and when a decomposed signal is the closely spaced mode signal, the mode mixing easily occurs when the HHT is used. Therefore, in the present invention, the interference signal and discontinuous signal are removed through the singular value decomposition and reconstruction, and the closely spaced mode signal is adjusted as the non-closely spaced mode signal through signal frequency modulation, preventing the occurrence of the mode mixing.

The determining whether the original voltage signal is a closely spaced mode signal includes:
for the original voltage signal α₁ cos(2πf₁t+φ₁)+α₂ cos(2πf₂t+φ₂),
when f₁/f₂>α is not met and α₁f₁>α₂f₂, determining that the original voltage signal is the closely spaced mode signal, where α₁ and α₂ are amplitudes of the corresponding signal, f₁ and f₂ are frequencies of the corresponding signal, and f₁>f₂, φ₁ and φ₂ are initial phase angles of the corresponding signal, and a is a set frequency ratio that is greater than 1.

It should be noted that when the frequencies of the signal are similar in the present invention, assuming that the amplitudes of the signal are the same, and the initial phases are also the same, the signal can be regarded as a special amplitude-modulated signal, and the signal meets that a mean value of extremum envelopes is zero and the number of zero-crossing points is the same as the number of extremum points or there is a difference of one, so the model mixing occurs when the HHT is directly used for decomposition. Therefore, frequency spectrum analysis needs to be performed on the original voltage signal to determine whether the mode mixing occurs. A signal with a larger value between signal frequencies f₁ and f₂ is selected to divide a signal with a smaller value to obtain a frequency ratio α. As the frequency ratio is greater, a frequency difference between the two signals is greater, which means that the mode mixing does not occur easily, and a frequency ratio of 2 can be selected as a standard for determining whether the original voltage signal is the closely spaced mode signal.

The performing singular value decomposition and reconstruction, to obtain a reconstructed voltage signal includes:
based on the original voltage signal x₀(i), (i=1,2, . . . , N), constructing a corresponding Hankel matrix H and performing the singular value decomposition, to obtain a singular value matrix

$$D = [ \begin{matrix}Σ & 0 \\ 0 & 0\end{matrix} ] ,$$

where the number of rows of the matrix H is m, the number of columns of the matrix H is n=N−m+1, a rank is r, Σ=diag (σ₁, σ₂, . . . , σᵣ) in the singular value matrix, and singular values meet σ₁>σ₂> . . . >σᵣ>0;
retaining singular values among the first effective singular values, setting singular values following the effective singular values to zero, and updating the singular value matrix; and
performing inverse operation of singular value decomposition on an updated singular value matrix, to obtain the reconstructed voltage signal x(i) with the interference signal removed.

It should be noted that the number of rows m in the Hankel matrix in the present invention is half of the length of the original voltage signal N. The voltage signal can be regarded as including a disturbance signal and an interference signal. In addition, because singular values in the singular value matrix are arranged in decreasing order, which reflects specific energy concentration of the signal, and the signal is decomposed based on specific singular values. A smaller singular value is set to 0, and the interference signal in the original voltage signal can be removed.

Specifically, the performing singular value decomposition and reconstruction to obtain a reconstructed original voltage signal is:
based on the original voltage signal x₀(i), (i=1,2, . . . , N), constructing the corresponding Hankel matrix H,

$$H = [ \begin{matrix}{x}_{0} ( 1 ) & {x}_{0} ( 2 ) & … & {x}_{0} ( N - m + 1 ) \\ {x}_{0} ( 2 ) & {x}_{0} ( 3 ) & … & {x}_{0} ( N - m + 2 ) \\ ⋮ & ⋮ & & ⋮ \\ {x}_{0} ( m ) & {x}_{0} ( m + 1 ) & … & {x}_{0} ( N )\end{matrix} ] .$$

The length of the original voltage signal is N, the number m of rows of the matrix is half of the length N of the signal, or half of N+1 is selected when N is odd, and the number of columns is n=N−m+1.

Singular value decomposition is performed on the Hankel matrix, and then

$$H = {UDV}^{T} ,$$

where U and D are respectively orthogonal matrices of a m×m dimension and n×n dimension, so that a singular value matrix

$$D = [ \begin{matrix}Σ & 0 \\ 0 & 0\end{matrix} ]$$

is obtained, where Σ=diag(σ₁, σ₂, . . . , σᵣ), singular values meet σ₁>σ₂> . . . >σᵣ>0, and a rank of the matrix H is r.

Singular values among the first effective singular values in the singular value matrix are retained, and other singular values are zeroed to obtain the updated singular value matrix. The number of effective singular values is the number of main frequencies of the original voltage signal multiplied by a set multiple. For the singular values among the first effective singular values, when a singular value is greater than p times a next singular value, all singular values following the singular value are set to zero, and p is a preset positive number less than 1. In the present invention, a set multiple is 2, and the value of p is selected as ⅕, that is, the number of effective singular values is twice the number of main frequencies of the original voltage signal. When a singular value is less than ⅕ of a previous singular value, the singular value and a next singular value are both set to zero.

Inverse operation of singular value decomposition is performed on the updated singular value matrix, to obtain an updated Hankel matrix and a reconstructed voltage signal x(i) with an interference signal removed. x(i) and x(t) are both the reconstructed voltage signals, the former mainly means a sequence of the reconstructed voltage signal, and the latter mainly means the change of the reconstructed voltage signal with time.

Further, in the present invention, it is determined that some singular values in the singular value matrix are set to zero, so that after the singular values following the number of the effective singular values are set to zero, the singular values among the first effective singular values are processed. If a numerical difference between two adjacent singular values is too large, it indicates that a next singular value and a singular value following the next singular value are interference signals, which also need to be set to zero. In the present invention, the number of effective singular values is determined based on the number of main frequencies in the frequency spectrum information, which may be twice of the number of the main frequencies. If there is a difference between two adjacent singular values, p=⅕ can be selected as a threshold.

In a specific embodiment, the steps of frequency modulation on the reconstructed voltage signal are as follows:
performing Hilbert transform on the reconstructed voltage signal x(t) to obtain an analytic signal X(t) thereof,

$$X ( t ) = x ( t ) + jH [ x ( t ) ] = {e}^{j {ω}_{1} t} + {e}^{j {ω}_{2} t} ,$$

where ω₁=2πf₁ and ω₂=2πf₂; and
selecting a proper modulation frequency ω₀ to perform frequency modulation and transform on the analytic signal X(t), that is, multiply e^{-jω}^{₀}^{t} to obtain the frequency-modulated signal

$$Z ( t ) = X ( t ) \cdot {e}^{- j {ω}_{0} t} = {Z}_{r} ( t ) + {jZ}_{j} ( t ) = {e}^{j ( {ω}_{1} - {ω}_{0} ) t} + {e}^{j ( {ω}_{2} - {ω}_{0} ) t} ,$$

where Zᵣ(t) is a transformed real part of the frequency-modulated signal Z(t), jZⱼ(t) is a transformed imaginary part of the frequency-modulated signal Z(t), and j is an imaginary number unit.

It should be noted that in the present invention, the original voltage signal is determined as the closely spaced mode signal, and then frequency modulation needs to be performed on the reconstructed voltage signal. Through signal frequency modulation, closely spaced mode separation can be implemented indirectly, preventing mode mixing caused by interaction of closely spaced modes. A core idea thereof is to subtract frequencies of adjacent modes from proper frequencies for frequency modulation through signal frequency modulation and amplify a frequency ratio, so that a frequency-modulated signal becomes a non-closely spaced mode signal, and then perform empirical mode decomposition on the frequency-modulated signal after the frequency modulation is completed.

Selection of the modulation frequency ω₀ needs to meet

$$\frac{{ω}_{1} - {ω}_{0}}{{ω}_{2} - {ω}_{0}} > α ,$$

where ω₁−ω₀>0, ω₂−ω₀>0.

In the present invention, when the modulation frequency is selected, a frequency ratio after frequency modulation needs to be greater than a set α, so that the original voltage signal is changed from the closely spaced mode signal to the non-closely spaced mode signal. For two frequencies with a frequency ratio less than α, a proper modulation frequency ω₀ is subtracted from both a numerator and denominator, so that signal frequencies are reduced and a frequency ratio of the signal is amplified to be greater than α, thereby completing frequency modulation.

In a specific embodiment, after the frequency modulation is completed, white noise is added to the real part and the imaginary part of the frequency-modulated signal Z(t) separately, and empirical mode decomposition and combination are performed, to obtain a decomposition expression of the frequency-modulated signal Z(t).

The decomposition expression of the frequency-modulated signal Z(t) is multiplied by e^{jω}^{₀}^{t} to obtain a decomposition expression of the analytic signal X(t), and a real part of the decomposition expression of the analytic signal X(t) is taken as a decomposition expression of the reconstructed voltage signal x(t), so that empirical mode decomposition of the reconstructed voltage signal is completed.

It should be noted that in the present invention, the empirical mode decomposition with white noise added is performed on the frequency-modulated signal, to obtain a sum of several intrinsic mode functions IMF and residuals. Then, through the frequency-modulation inverse transformation on the intrinsic mode function IMF, intrinsic mode functions IMFs of a real reconstructed voltage signal are obtained. Empirical mode decomposition is performed on the real part and imaginary part of the frequency-modulated signal constructed from the reconstructed voltage signal, preventing mode mixing caused by direct empirical mode decomposition on the voltage signal.

First, a process of the empirical mode decomposition after noise is added to the signal is described as follows:
adding Gaussian white noise with a mean value of 0 to the reconstructed voltage signal x(t) K times to form K subsequences to be decomposed;
averaging first mode components obtained by EMD on the K subsequences to be decomposed, using an average as a first mode component sequence IMF₁(t) of x(t), and calculating a first residual signal r₁(t);
adding a first mode component of the Gaussian white noise to the first residual signal r₁(t), continuing the EMD, to obtain a second mode component sequence IMF₂(t) of x(t), and calculating a second residual signal r₂(t); and
repeating the above steps, and completing decomposition, to obtain K mode component sequences and one residual component sequence.

It should be noted that a fully adaptive noise ensemble empirical mode decomposition is used, a mode component containing auxiliary noise after EMD is added, and a first-order mode component IMF is calculated by overall average calculation in a first stage of decomposition. Then, adding auxiliary noise and decomposition are repeatedly performed on a residual part, and finally, K mode component sequences and one residual component sequence are obtained. Compared with an ordinary EMD, the fully adaptive noise ensemble empirical mode decomposition can effectively prevent mode mixing.

Specifically, a process of empirical mode decomposition on the reconstructed voltage signal or frequency-modulated signal includes:
adding Gaussian white noise with a mean value of 0 to the reconstructed voltage signal x(t) to be decomposed K times to form K subsequences to be decomposed,

$${x}_{i} ( t ) = x ( t ) + {εδ}_{i} ( t ) ,$$

where ε is a weight coefficient of the Gaussian white noise, and δᵢ(t) is Gaussian white noise added to an i^{th} sequence to be decomposed, i ∈[1, K];
averaging first mode components obtained by EMD on the K subsequences to be decomposed, using an average as a first mode component sequence IMF₁(t) of x(t), and calculating a first residual signal r₁(t),

$${IMF}_{1} ( t ) = \frac{1}{K} {\sum }_{i = 1}^{K} {IMF}_{1}^{i} ( t ) , \\ {r}_{1} ( t ) = x ( t ) - {IMF}_{1} ( t ) ,$$

where IMF₁ⁱ(t) means a first mode component obtained by EMD on an i^{th} subsequence to be decomposed; and
adding a (j−1)^{th} mode component of Gaussian white noise to a (j−1)^{th} residual signal rⱼ₋₁(t), continuing the EMD, to obtain a j^{th} mode component sequence IMFⱼ(t) of x(t), and calculating a j^{th} residual signal rⱼ (t),

$${IMF}_{j} ( t ) = \frac{1}{K} {\sum }_{i = 1}^{K} {E}_{1} ( {r}_{j - 1} ( t ) + {ε}_{j - 1} {E}_{j - 1} ( {δ}_{i} ( t ) ) ) , \\ {r}_{j} ( t ) = {r}_{j - 1} ( t ) - {IMF}_{j} ( t ) ,$$

where Eⱼ₋₁(·) means the (j−1)^{th} mode component after EMD on the sequence, and εⱼ₋₁ means a weight coefficient of noise added to the (j−1)^{th} residual signal.

The above steps are repeated until an EMD stop condition is met. When a residual signal in a K^{th} decomposition is a monotonic signal, decomposition is completed, to obtain K mode component sequences and one residual component sequence.

After the frequency modulation is completed, white noise is added to the real part and the imaginary part of the frequency-modulated signal Z(t) respectively, and the empirical mode decomposition is performed, to obtain

$$\{ \begin{matrix}{Z}_{r} ( t ) = {\sum }_{k = 1}^{n} {C}_{rk} ( t ) + {r}_{nr} \\ {Z}_{j} ( t ) = {\sum }_{k = 1}^{n} {C}_{jk} ( t ) + {r}_{nj}\end{matrix} ,$$

where Cᵣₖ(t) is an intrinsic mode function IMF obtained by decomposition of the real part of the signal, and Cⱼₖ(t) is an intrinsic mode function IMF obtained by decomposition of the imaginary part of the signal; and rₙᵣ and rₙⱼ are respectively corresponding decomposed residuals. After combination, a decomposition expression of the frequency-modulated signal Z(t) is obtained as follows

$$Z ( t ) = {\sum }_{k = 1}^{n} ( {C}_{rk} ( t ) + {C}_{jk} ( t ) ) + ( {r}_{nr} + {r}_{nj} ) .$$

The decomposition expression of the frequency-modulated signal Z(t) is multiplied by e^{jω}^{₀}^{t}, to obtain a decomposition expression of the analytic signal X(t),

$$X ( t ) = Z ( t ) \cdot {e}^{j {ω}_{0} t} = {\sum }_{k = 1}^{n} ( {C}_{rk} ( t ) + {C}_{jk} ( t ) ) \cdot {e}^{j {ω}_{0} t} + ( {r}_{nr} + {r}_{nj} ) \cdot {e}^{j {ω}_{0} t} .$$

A real part of the decomposition expression of the analytic signal X(t) is taken as a decomposition expression of the reconstructed voltage signal x(t),

$$x ( t ) = Re ( X ( t ) ) .$$

In this way, the empirical mode decomposition of the reconstructed voltage signal is completed.

Hilbert transform is performed on each obtained intrinsic mode function after empirical mode decomposition is completed, to obtain amplitude and frequency information of the corresponding intrinsic mode function, and detection of voltage quality disturbance is completed.

Specifically, the Hilbert transform is performed on the intrinsic mode function IMFᵢ(t), to obtain γᵢ(t)=HT(IMFᵢ(t)), where HT(·) is an expression function of the Hilbert transform, and * is convolution;

$${y}_{i} ( t ) = HT ( {IMF}_{i} ( t ) ) = \frac{1}{π} {\int }_{- ∞}^{+ ∞} \frac{{IMF}_{i} ( τ )}{t - τ} d τ = {IMF}_{i} ( t ) * \frac{1}{π t} ,$$

and then a composite analytical signal zᵢ(t)=IMFᵢ(t)+j·γᵢ(t) is obtained.

Based on the analytical signal zᵢ(t), an instantaneous amplitude of a IMFᵢ(t) component can be Aᵢ(t)={square root over ((IMFᵢ(t))²+(γᵢ(t))²)}, and an instantaneous frequency is ωᵢ(t)=d(θᵢ(t))/dt, where an instantaneous phase is θᵢ(t)=arctan(γᵢ(t)/IMFᵢ(t)).

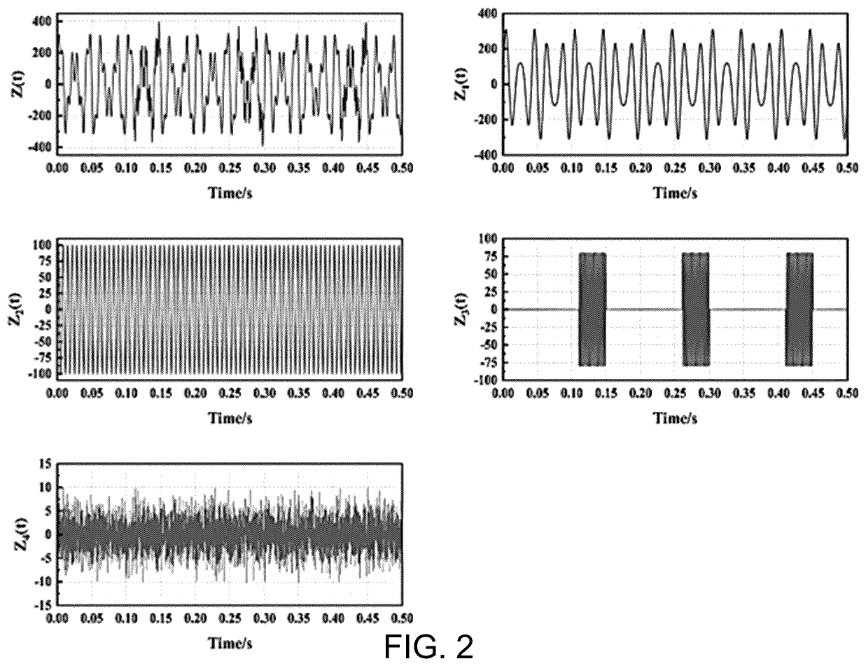

In an embodiment of the present invention, a reconstructed voltage signal x(t) shown in FIG. 2 is selected, which can be divided into four parts, which are specifically: a closely spaced mode signal x₁(t), containing a fundamental voltage of 220V, 50 Hz and a harmonic with an amplitude of 100V and a frequency of 70 Hz; a 3rd harmonic x₂(t) with an amplitude of 100V; a high-frequency intermittent harmonic x₃(t) with an amplitude of 80V and a frequency of 450 Hz, and with unchanged amplitude and a phase in detection time; and finally an intermittent Gaussian white noise x₄(t) of 10 dB:

$$\{ \begin{matrix}x ( t ) = {x}_{1} ( t ) + {x}_{2} ( t ) + {x}_{3} ( t ) + {x}_{4} ( t ) \\ {x}_{1} ( t ) = 220 sin ( 100 πt ) + 100 sin ( 140 πt ) \\ {x}_{2} ( t ) = 100 sin ( 300 πt ) \\ {x}_{3} ( t ) \\ {x}_{4} ( t )\end{matrix} .$$

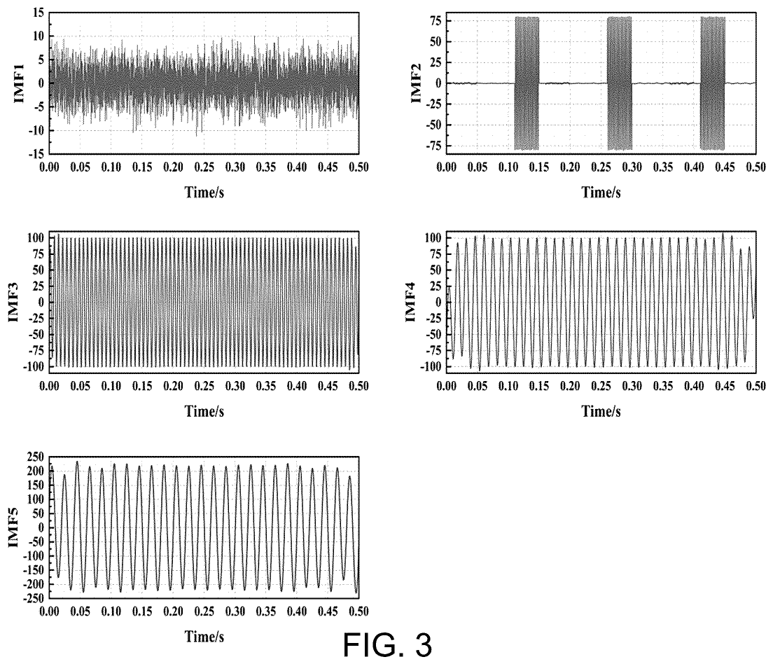

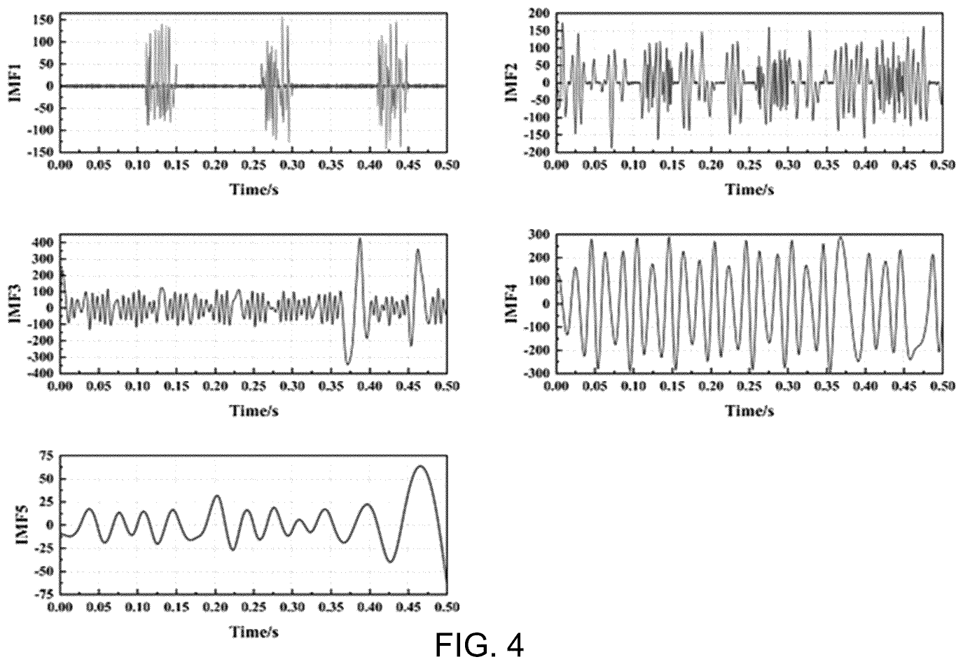

Intrinsic mode functions obtained through empirical mode decomposition in the detection method of the present invention are shown in FIG. 3, and intrinsic mode functions obtained by directly performing empirical mode decomposition are shown in FIG. 4. It can be learned that compared with direct use of empirical mode decomposition, the voltage quality disturbance detection method in the present invention can resolve the problem of mode mixing existing in the voltage signal, thereby improving the accuracy of the voltage quality disturbance detection.

The above embodiments are further elaborations and descriptions of the present invention for ease of understanding and are not any limitation of the present invention. Any modifications, equivalent substitutions, improvements, and the like made within the spirit and principle of the present invention should be included within the protection scope of the present invention.

What is claimed is:

1. A Hilbert-Huang Transform based (HHT-based) voltage quality disturbance detection method, comprising:
obtaining frequency spectrum information of an original voltage signal, and determining whether the original voltage signal is a closely spaced mode signal;
based on the frequency spectrum information, performing a singular value decomposition on the original voltage signal and performing a reconstruction to obtain a reconstructed voltage signal with an interference signal removed;
if the original voltage signal is the closely spaced mode signal, performing a frequency modulation on the reconstructed voltage signal to obtain a frequency-modulated signal;
adding white noise to the reconstructed voltage signal or the frequency-modulated signal, and then performing an empirical mode decomposition; and
performing a Hilbert transform on each of a plurality of intrinsic mode functions obtained by the empirical mode decomposition to obtain an amplitude and frequency information of a corresponding intrinsic mode function, and finishing a detection of voltage quality disturbance.

2. The HHT-based voltage quality disturbance detection method according to claim 1, wherein performing the singular value decomposition on the original voltage signal and performing reconstruction to obtain the reconstructed voltage signal with the interference signal removed comprises:
based on the original voltage signal x₀(i), i=1,2, . . . , N, constructing a corresponding Hankel matrix H and performing the singular value decomposition, to obtain a singular value matrix
$$D = [ \begin{matrix}Σ & 0 \\ 0 & 0\end{matrix} ] ,$$
wherein the number of rows of the matrix H is m, the number of columns of the matrix H is n=N−m+1, a rank is r, Σ=diag (σ₁, σ₂, . . . , σᵣ) in the singular value matrix, and singular values meet σ₁>σ₂> . . . >σᵣ>0;
retaining singular values among the first effective singular values, setting singular values following the first effective singular values to zero, and updating the singular value matrix; and
performing an inverse operation of singular value decomposition on an updated singular value matrix to obtain the reconstructed voltage signal x(i) with the interference signal removed.

3. The HHT-based voltage quality disturbance detection method according to claim 1, wherein adding white noise to the reconstructed voltage signal and performing the empirical mode decomposition comprises:
adding a Gaussian white noise with a mean value of 0 to the reconstructed voltage signal x(t) K times to form K subsequences to be decomposed;
averaging first mode components obtained by EMD on the K subsequences to be decomposed, using an average as a first mode component sequence IMF₁(t) of x(t), and calculating a first residual signal r₁(t);
adding a first mode component of the Gaussian white noise to the first residual signal r₁(t), continuing the EMD, to obtain a second mode component sequence IMF₂(t) of x(t), and calculating a second residual signal r₂(t); and
repeating the above steps, and completing decomposition, to obtain K mode component sequences and one residual component sequence.

4. The HHT-based voltage quality disturbance detection method according to claim 2, wherein the number of the first effective singular values is the number of main frequencies of the original voltage signal multiplied by a set multiple; and
for the singular values among the first effective singular values, when a singular value is greater than p times a next singular value, all singular values following the singular value are set to zero, and p is a preset positive number less than 1.

5. The HHT-based voltage quality disturbance detection method according to claim 1, wherein performing the frequency modulation on the reconstructed voltage signal comprises:
performing the Hilbert transform on the reconstructed voltage signal x(t) to obtain an analytic signal X(t) thereof,
$$X ( t ) = x ( t ) + jH [ x ( t ) ] = {e}^{j {ω}_{1} t} + {e}^{j {ω}_{2} t} ,$$
wherein ω₁=2πf₁ and ω₂=2πf₂; and
selecting a modulation frequency ω₀ to perform frequency modulation and transform on the analytic signal X(t), to obtain the frequency-modulated signal
$$Z ( t ) = X ( t ) \cdot {e}^{- j {ω}_{0} t} = {Z}_{r} ( t ) + {jZ}_{j} ( t ) = {e}^{j ( {ω}_{1} - {ω}_{0} ) t} + {e}^{j ( {ω}_{2} - {ω}_{0} ) t} ,$$
wherein Zᵣ(t) is a transformed real part of the frequency-modulated signal Z(t), and jZⱼ(t) is a transformed imaginary part of the frequency-modulated signal Z(t).

6. The HHT-based voltage quality disturbance detection method according to claim 5, wherein after the frequency modulation is completed, the white noise is respectively added to the real part and the imaginary part of the frequency-modulated signal Z(t) for performing the empirical mode decomposition, and then a combination operation is performed to obtain a decomposition expression of the frequency-modulated signal Z(t); and
wherein the decomposition expression of the frequency-modulated signal Z(t) is multiplied by e^{jω}^{₀}^{t} to obtain a decomposition expression of the analytic signal X(t), and a real part of the decomposition expression of the analytic signal X(t) is taken as a decomposition expression of the reconstructed voltage signal x(t), so that the empirical mode decomposition of the reconstructed voltage signal is completed.

7. The HHT-based voltage quality disturbance detection method according to claim 1, wherein determining whether the original voltage signal is the closely spaced mode signal comprises:
for the original voltage signal α₁ cos(2πf₁t+φ₁)+α₂ cos(2πf₂t+φ₂),
when f₁/f₂>α is not met and α₁fᵢ>α₂f₂, determining that the original voltage signal is the closely spaced mode signal, wherein α₁ and α₂ are amplitudes of the corresponding signal, f₁ and f₂ are frequencies of the corresponding signal, and f₁>f₂, φ₁ and φ₂ are initial phase angles of the corresponding signal, and a is a set frequency ratio that is greater than 1.

8. The HHT-based voltage quality disturbance detection method according to claim 5, wherein selecting the modulation frequency ω₀ needs to meet:
$$\frac{{ω}_{1} - {ω}_{0}}{{ω}_{2} - {ω}_{0}} > α$$
wherein ω₁−ω₀>0, φ₂31 ω₀>0.

9. The HHT-based voltage quality disturbance detection method according to claim 1, wherein obtaining the amplitude and frequency information of the corresponding intrinsic mode function comprises:
performing the Hilbert transform on the intrinsic mode function IMF₁(t) to obtain γᵢ(t)=HT(IMFᵢ(t)), wherein HT(·) is an expression function of the Hilbert transform,
wherein an amplitude of the intrinsic mode function IMFᵢ(t) is Aᵢ(t)={square root over ((IMFᵢ(t))²+(γᵢ(t))²)}, and a frequency of the intrinsic mode function IMFᵢ(t) is ωᵢ(t)=d(θᵢ(t))/dt,
wherein θᵢ(t)=arctan(γᵢ(t)/IMFᵢ(t)).
